(19) United States
(12) Patent Application Publication
(10) Pub. No.: US 2009/0149227 A1
(43) Pub. Date: Jun. 11, 2009

(54) CASING AND ELECTRONIC DEVICE

(75) Inventor: Shingo YAMAGUCHI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/251,837

(22) Filed: Oct. 15, 2008

(30) Foreign Application Priority Data
Dec. 11, 2007 (JP) 2007-319954

(51) Int. Cl. H04M 1/02; H05K 5/03

(52) U.S. Cl. 455/575.3; 361/679.01

(57) ABSTRACT

A casing includes an adhesive member, a pair of casing members bonded together with the adhesive member, and a tube including a fluid inlet and having an elasticity. And the tube expands along with injection of a fluid into the tube from the fluid inlet to detach the bonded casing members based on an expansion force of the tube.

### BACKGROUND

1. Field of the Invention

The present invention relates to a structure for efficiently disassembling a casing member attached to an electronic device.

2. Description of the Related Art

Hitherto, a bonding method using a screw, a double-adhesive tape, or an adhesive has been often used for assembly of a resin panel or metal sheet of an electronic device. To disassemble the resin panel or metal sheet, a method of unscrewing and disassembling the panel or the sheet or a method of directly applying an external force to the panel or the sheet to detaching the panel or the sheet has been employed. However, in the case of screwing the panel or the sheet, if many screws are used for the panel or the sheet, it takes a lot of trouble to assemble or disassemble the panel or sheet. In addition, such a screwed structure cannot be applied to a small electronic device. Further, in the case of directly applying an external force to the resin panel or metal sheet for disassembly, if a recess to add the external force is formed to the panel or the sheet, the panel or the sheet can be easily disassembled. However, some devices do not form the recess to the panel or the sheet because of being developed with emphasis on good-looking design etc. Thus, it is difficult to disassemble the panel or the sheet. Even if the panel or the sheet can be disassembled, it might be damaged. Moreover, special tools are often required for disassembly, which increases a cost in some cases and requires a high-level disassembly skill.

### SUMMARY

Accordingly, it is an object of the present technique to provide a casing structured to easily disassemble an attached casing member, and an electronic device having the casing.

According to an aspect of an embodiment, a casing includes an adhesive member, a pair of casing members, and a tube. The casing members are bonded together with the adhesive member. The tube is provided between the casing members. The tube includes a fluid inlet and has an elasticity. The tube expands along with injection of a fluid into the tube from the fluid inlet to detach the bonded casing members based on an expansion force of the tube.

### BRIEF DESCRIPTION OF THE DRAWINGS

FIGS. 1A and 1B show an outer appearance of a folding cellular phone;

FIGS. 2A and 2B are first explanatory views of a casing of a display unit of the cellular phone according to a first embodiment;

FIG. 3 is a second explanatory view of the casing of the display unit of the cellular phone of the first embodiment;

FIG. 4 is a partially sectional view of the casing of the display unit of the first embodiment;

FIGS. 5A and 5B are explanatory views of an inlet;

FIGS. 6A to 6C are explanatory views of a casing separation mechanism of the first embodiment;

FIGS. 7A and 7B show a shape of a tube holding groove of the first embodiment;

FIG. 8 is an explanatory view of a casing of a display unit of a cellular phone according to a second embodiment; and

FIG. 9 is an explanatory view of a casing separation mechanism of the second embodiment.

### DESCRIPTION OF THE PREFERRED EMBODIMENTS

### First Embodiment

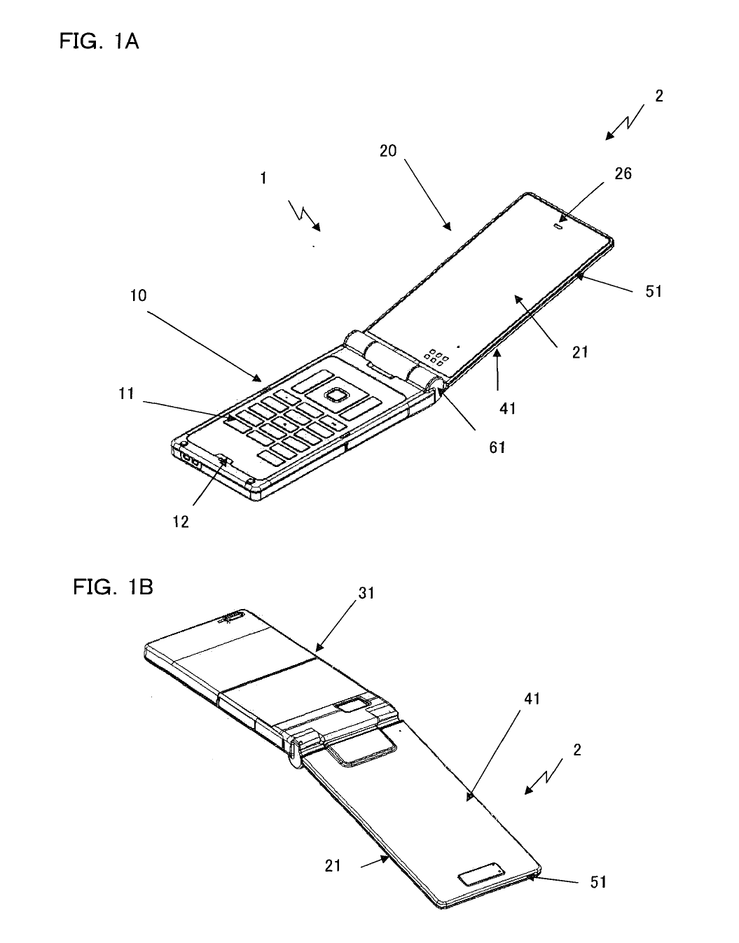

FIGS. 1A and 1B show an outer appearance of a folding cellular phone 1. FIG. 1A shows the opened cellular phone 1 as viewed from an operation panel side. The cellular phone 1 includes a main body unit 10 and a display unit 20. The display unit 20 is coupled with the main body unit 10 through an opening/closing unit 61. The main body unit 10 has many keys 11. The keys 11 are operated by a user to enter various kinds of information such as a telephone number. A mouthpiece 12 is provided at a lower end portion of the main body unit 10. Further, the display unit 20 is equipped with a transparent front cover that allows a user to see displayed contents therethrough. An ear piece 26 for outputting a voice is provided in an upper portion of the main body unit 10.

FIG. 1B shows the opened folding cellular phone as viewed from the back side. A rear cover 31 of the main body unit 10 of the cellular phone 1 is put on the rear side of the main body unit 10, and a rear cover 41 of the display unit 20 is put on the rear side of the display unit 20. A casing 2 of the display unit 20 includes a front cover 21, a base unit 51, and the rear cover 41, which are layered in this order. The base unit 51 is bonded with the front cover 21 and the rear cover 41 with an adhesive material, respectively. The individual units are detailed later.

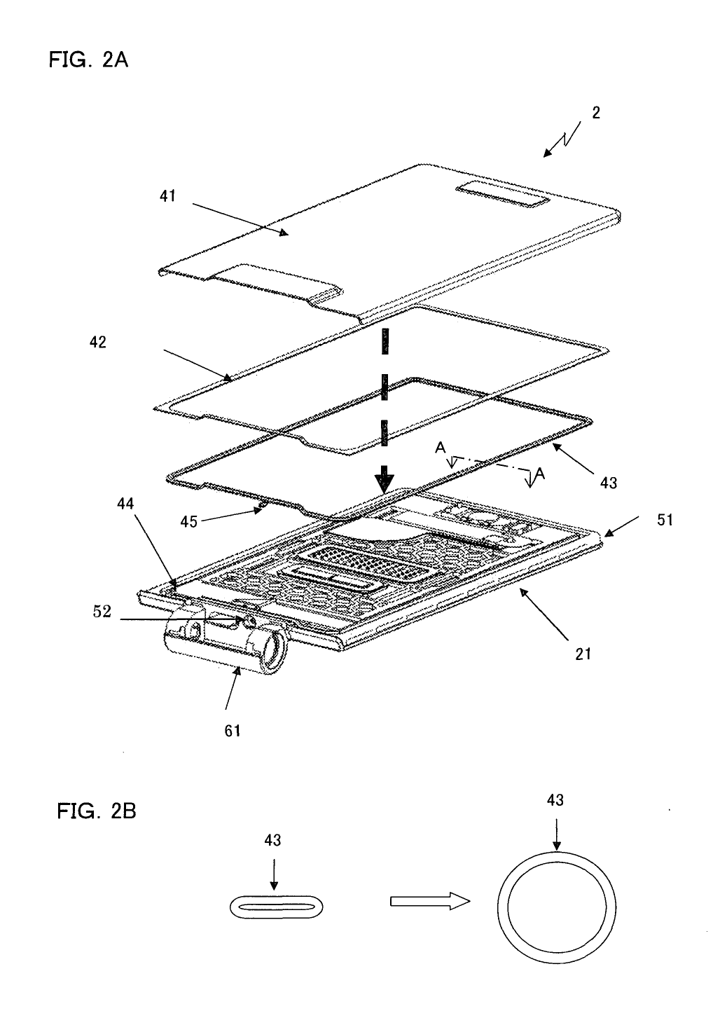

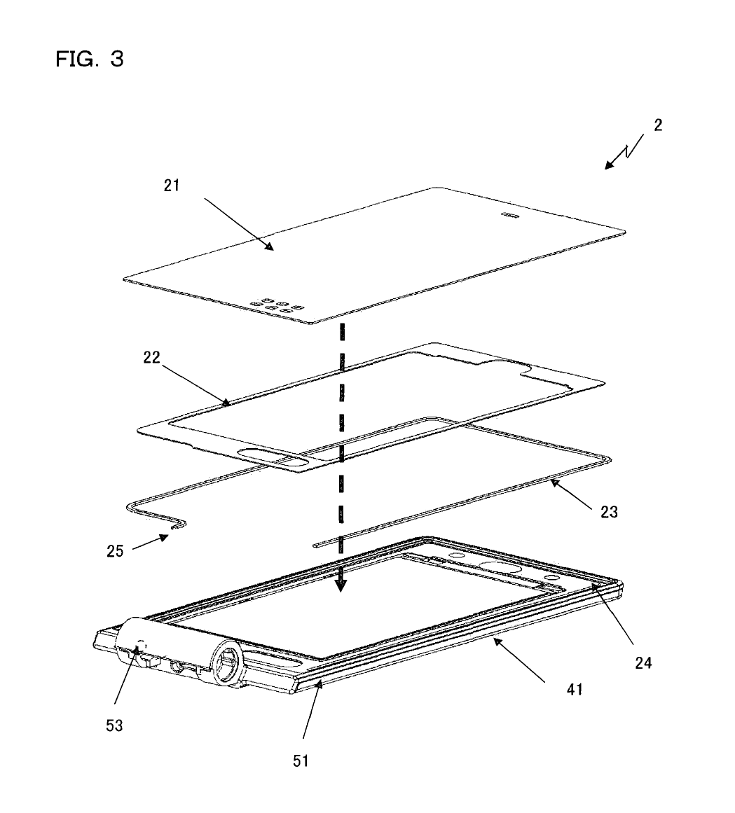

FIGS. 2A and 2B are first explanatory views of the casing 2 of the display unit 20 of the cellular phone 1 according to a first embodiment. FIG. 2A is an explanatory view of the casing 2 as viewed from the back side in FIG. 1B. The casing 2 of the display unit 20 includes the rear cover 41, a double-adhesive tape 42, a thin film tube 43, the base unit 51, the front cover 21, a double-adhesive tape 22, and a thin film tube 23. The front cover 21, the double-adhesive tape 22, and the thin film tube 23 are detailed below with reference to FIG. 3. FIGS. 2A and 2B illustrate how to attach the rear cover 41 to the base unit 51 of the display unit 20.

The double-adhesive tape 42 is used as an adhesive material for attaching the rear cover 41 to the base unit 51. Further, the thin film tube 43 is used to detach the rear cover 41 from the base unit 51. The rear cover 41 is formed of sheet metal. The sheet metal is, for example, aluminum or titanium. The rear cover 41 can be formed with the resin. The double-adhesive tape 42 is used to bond the rear cover 41 to the base unit 51. The rear cover 41 and the base unit 51 may be bonded together with an adhesive bond, not the double-adhesive tape 42. The adhesive bond is, for example, an epoxy resin bond.

The base unit 51 is a casing member for mounting electronic components such as a processor and a display unit including liquid crystal glass. The base unit 51 includes an opening/closing unit 61 as a coupling with the main body unit 10. Further, the base unit 51 has a tube holding groove 44 for holding the thin film tube 43 used for detaching the rear cover 41 from the base unit 51.

The tube holding groove 44 has a depth of 1 mm and a width of 1 mm, in this embodiment. In this embodiment, the tube holding groove 44 has a closed-loop shape and is formed adjacent to a bonding surface of the rear cover 41 to be bonded to the base unit 51 with the double-adhesive tape 42. Because the bonding surface has a closed-loop shape, the tube holding groove 44 is also formed into a closed-loop shape. In addition, an expansion force of the thin film tube 43 can be effectively applied upon detachment because the tube holding groove 44 is adjacent to the bonding surface. As a result, the rear cover 41 and the base unit 51 can flake off easily. The bottom portion of the tube holding groove 44 has a semicircular sectional shape, an inverted trapezoid sectional shape, or an inverted triangle sectional shape as viewed in a depth direction. Thus, the thin film tube 43 moves toward the center of the bottom portion of the tube holding groove 44 if a fluid is filled thereinto.

The thin film tube 43 is used to detach the rear cover 41 from the base unit 51. The thin film tube 43 is formed in a closed-loop shape and fit in the tube holding groove 44 of the base unit 51. Further, the thin film tube 43 is elastic and has a fluid inlet 45. The fluid is, for example, air or helium etc. In this embodiment, the fluid is air. The air is injected from the outside to the inlet 45 through an inlet hole A52 formed in the base unit 51 using an air pump. If the thin film tube 43 expands and increases its diameter beyond the sum of the depth of the tube holding groove 44 and the thickness of the double-adhesive tape 42, the tube lifts the rear cover 41. As a result, if an expansion force of the thin film tube 43 exceeds the adhesion of the double-adhesive tape 42, the rear cover 41 bonded with the double-adhesive tape 42 is detached from the base unit 51. Examples of a material for the thin film tube 43 include silicon rubber or polyester. FIG. 2B is a sectional view of the thin film tube 43 taken along the line A-A of FIG. 2A. The thin film tube 43 takes an ellipsoidal shape before injection of the air and takes a circular shape after the injection of the air.

Next, how to assemble components between the rear cover 41 and the base unit 51 will be described. First, the thin film tube 43 is set in the tube holding groove 44 of the base unit 51. Next, the double-adhesive tape 42 is applied to the tube holding groove 44 of the base unit 51. Then, the bonding surface of the rear cover 41 is pressed against the double-adhesive tape 42 and bonded thereto. As a result, the rear cover 41 is bonded to the base unit 51.

FIG. 3 is a second explanatory view of the casing 2 of the display unit 20 of the cellular phone 1 of the first embodiment. FIG. 3 illustrates the casing 2 as viewed from the front cover 21 of FIG. 1A and illustrates how to bond the front cover 21 to the base unit 51 of the display unit 20. A double-adhesive tape 22 is used to bond the front cover 21 to the base unit 51. Further, a thin film tube 23 is used to detach the front cover 21 from the base unit 51.

The front cover 21 is made up of a transparent resin panel that allows a user to see a display portion therethrough. The resin panel is formed of, for example, an acrylic resin or polycarbonate. An untransparent resin panel may be used for any portion other than the display portion. In this case, a resin material such as ABS or sheet metal can be used. The base unit 51 includes a tube holding groove 24 for holding the thin film tube 23 to detach the front cover 21 from the base unit 51.

The tube holding groove 24 has a depth of 1 mm and a width of 1 mm, in this embodiment. The tube holding groove 24 has a substantially U-shaped form and is formed adjacent to a bonding surface of the front cover 21 to be bonded to the base unit 51 with the double-adhesive tape 22. In this embodiment, while the bonding surface has a closed-loop shape, the tube holding groove 24 is substantially U-shaped. In addition, an expansion force of the thin film tube 23 can be effectively applied upon detachment because the tube holding groove 24 is adjacent to the bonding surface. As a result, the rear cover 21 bonded to the base unit 51 can be easily detached therefrom. The bottom portion of the tube holding groove 24 has a semicircular sectional shape, an inverted trapezoid sectional shape, or an inverted triangle sectional shape as viewed in a depth direction. Thus, the thin film tube 23 moves toward the center of the bottom portion of the tube holding groove 24 if a fluid is filled thereinto.

The thin film tube 23 is used to detach the double-adhesive tape 42 from the base unit 51. The thin film tube 23 is substantially U-shaped. The thin film tube 23 is fit in the tube holding groove 24 of the base unit 51 and used to detach the front cover 21 on its three sides. Further, the thin film tube 23 is elastic and has a fluid inlet 25. A fluid is, for example, air or helium etc. In this embodiment, the fluid is air. The air is injected from the outside to the inlet 25 through an inlet hole B53 formed in the base unit 51 using an air pump. If the thin film tube 23 expands and increases its diameter beyond the sum of the depth of the tube holding groove 24 and the thickness of the double-adhesive tape 22, the tube lifts the front cover 21. As a result, if an expansion force of the thin film tube 23 exceeds the adhesion, the front cover 21 bonded with the double-adhesive tape 22 is detached from the base unit 51.

Next, how to assemble components between the front cover 21 and the base unit 51 will be described. First, the thin film tube 23 is fit in the tube holding groove 24 of the base unit 51. Next, the double-adhesive tape 22 is applied to the bonding surface of the base unit 51. Then, the bonding surface of the front cover 21 is pressed against the double-adhesive tape 22 and bonded thereto. As a result, the front cover 21 is bonded to the base unit 51.

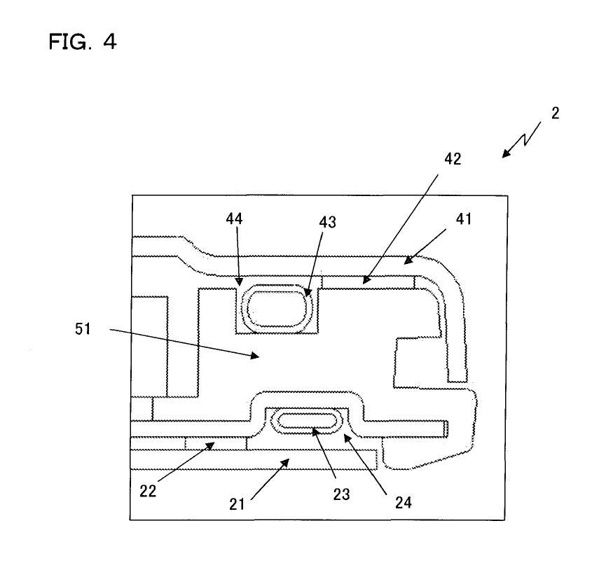

FIG. 4 is a partially sectional view of the casing 2 of the display unit 20 of the first embodiment. The casing 2 of the display unit 20 includes the front cover 21, the rear cover 41, the double-adhesive tape 22, the double-adhesive tape 42, the thin film tube 23, the thin film tube 43, and the base unit 51. The front cover 21 and the base unit 51 are bonded together with the double-adhesive tape 22. The thin film tube 23 is set in the tube holding groove 24. Further, the base unit 51 and the rear cover 41 are bonded with the double-adhesive tape 42. The thin film tube 43 is fit in the tube holding groove 44. The thin film tube 23 and the thin film tube 43 differ in terms of sectional shape before air injection.

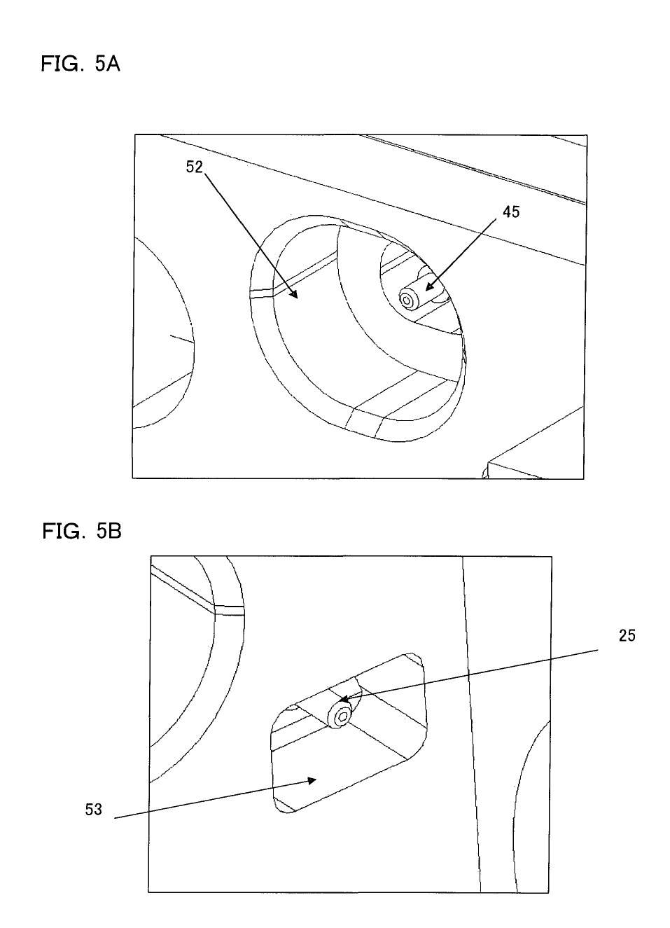

FIGS. 5A and 5B are explanatory views of the inlet 45. As shown in FIG. 5A, the inlet 45 of the thin film tube 43 is formed in alignment with the inlet hole A52 on the base unit 51 side. At the time of injecting air to the thin film tube 43, an air pump is inserted to the inlet 45 of the thin film tube 43 through the inlet hole A52 on the base unit 51 side. Next, air is pumped into the thin film tube 43 using the air pump. A back-flow valve or other such structure is unnecessary for the inlet 45 of the thin film tube 43 because no trouble occurs unless an air leaks upon injection. The inlet hole A52 of the base unit 51 may be set opened if being formed in an externally invisible position but may be covered with an additional component if the hole is formed in an externally visible position and required to be hidden. Further, as shown in FIG. 5B, the inlet 25 of the thin film tube 23 is formed in alignment with the inlet hole B53 on the base unit 51 side.

A back-flow valve or other such structure is unnecessary for the inlet 25 of the thin film tube 23 because no trouble occurs unless an air leaks upon injection. The inlet hole B53 of the base unit 51 may be set opened if being formed in an externally invisible position but may be covered with an additional component if the hole is formed in an externally visible position and required to be hidden.

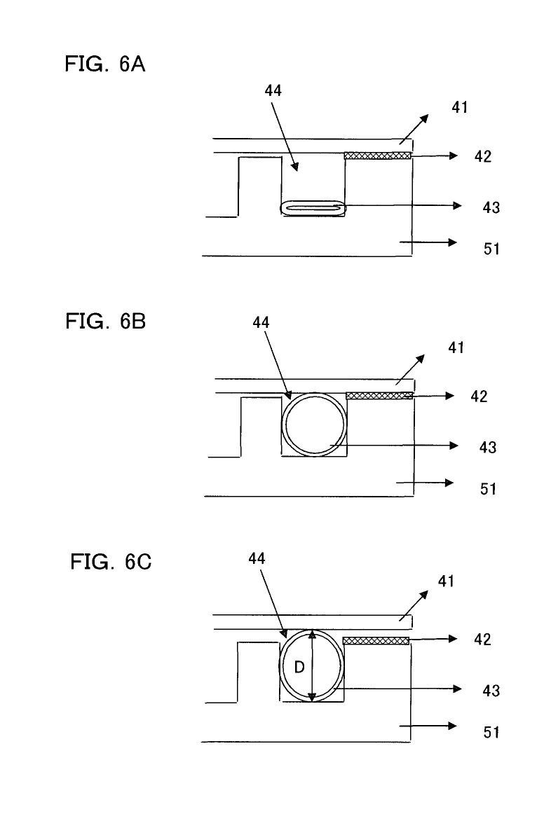

FIGS. 6A to 6C are explanatory views of a casing separation mechanism of the first embodiment. FIG. 6A shows how the thin film tube 43 is set when no air is filled thereinto. In the illustrated example, the rear cover 41 and the base unit 51 are bonded together with the double-adhesive tape 42. Thus, the tube holding groove 44 is covered with the rear cover 41. FIG. 6B shows how the thin film tube 43 is set when a fluid such as an air is filled thereinto. In the illustrated example, the thin film tube 43 expands as a result of injecting the air thereinto and lifts the rear cover 41 covering the tube holding groove 44. Then, the double-adhesive tape 42 that bonds the rear cover 41 to the base unit 51 begins to peel off. As described above, in order to peel off the double-adhesive tape 42 along with the expansion of the thin film tube 43, the diameter of the expanded thin film tube 43 needs to exceed the sum of the depth of the tube holding groove 44 and the thickness of the double-adhesive tape 42. FIG. 6C is an explanatory view of the maximum dimension of the thin film tube 43 and the tube holding groove 44. If the diameter of the thin film tube 43 exceeds the sum of the depth of the tube holding groove 44 and the thickness of the double-adhesive tape 42, the rear cover 41 bonded to the base unit 51 begins to peel therefrom. Then, when the thin film tube 43 reaches the maximum diameter D as a result of continuing the air injection to the thin film tube 43, and increases its internal pressure beyond the adhesion, the rear cover 41 bonded to the base unit 51 peels therefrom.

Further, a casing separation mechanism for the front cover 21 and the base unit 51 is similar to the separation mechanism for the rear cover 41 and the base unit 51. More specifically, the front cover 21 corresponds to the rear cover 41, the double-adhesive tape 22 corresponds to the double-adhesive tape 42, the thin film tube 23 corresponds to the thin film tube 43, and the tube holding groove 24 corresponds to the tube holding groove 44.

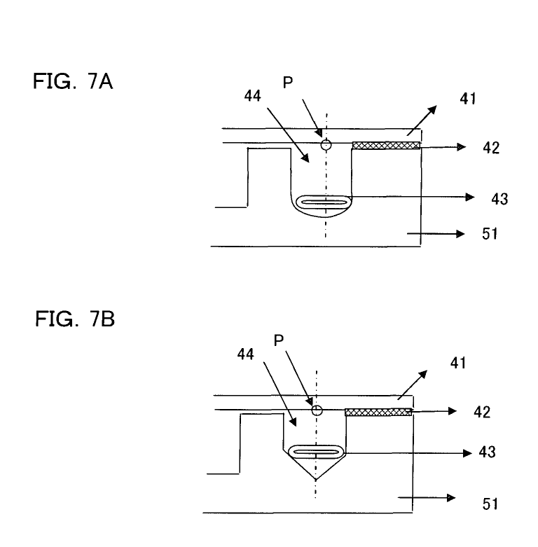

FIGS. 7A and 7B are explanatory views of the shape of the tube holding groove of the embodiment. FIGS. 7A and 7B show an example where the double-adhesive tape 42 is applied to a bonding portion that is an outer edge of the base unit 51. In this case, the top of the center axis of the thin film tube 43 is set aligned with a point P of the base unit 41 corresponding to the midpoint of the width of the tube holding groove 44. To attain this structure, it is necessary to determine the bottom shape of the tube holding groove 44 such that the center of the thin film tube 43 corresponds to the point P of the rear cover at any rate. For that purpose, the tube holding groove 44 is formed into a semi-circular sectional shape as shown in FIG. 7A or an inverted triangle sectional shape as shown in FIG. 7B. Alternatively, the tube holding groove 44 may be formed into an inverted trapezoid sectional shape. With this structure, the thin film tube 43 can automatically move to the center of the tube holding groove 44 and expands when being filled with the air and therefore, an expansion force acts around the point P. As a result, the expansion force of the thin film tube 43 is applied to the double-adhesive tape 42 in a position close to the bonding portion of the base unit 51, so the double-adhesive tape 42 can be efficiently peeled off. If the tube holding groove 44 is formed so as to set the point P closer to the bonding portion of the base unit 51, the double-adhesive tape 42 can be more efficiently peeled off.

### Second Embodiment

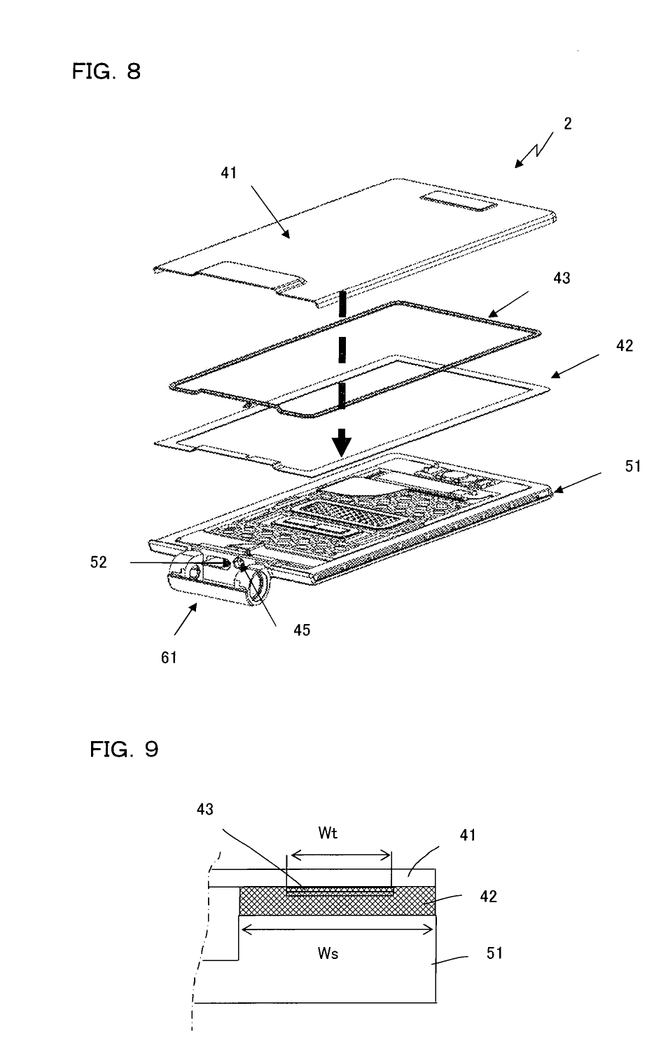

FIG. 8 is an explanatory view of a casing 2 of a display unit 20 of a cellular phone 1 according to a second embodiment. FIG. 8 illustrates how the rear cover 41 is attached to the base unit 51 of the display unit 20 of FIGS. 1A and 1B. FIG. 8 illustrates the casing 2 as viewed from the back side in FIG. 1B. The double-adhesive tape 42 is used as an adhesive material for attaching the rear cover 41 to the base unit 51. Further, the thin film tube 43 is used to detach the rear cover 41 from the base unit 51. The rear cover 41, the double-adhesive tape 42, and the thin film tube 43 are the same as those of the first embodiment. The base unit 51 is the same as that of the first embodiment except that the tube holding groove 44 is not provided.

Next, how to assemble components between the rear cover 41 and the base unit 51 will be described. First, the double-adhesive tape 42 is applied to the bonding surface of the base unit 51. Then, the thin film tube 43 is bonded to the double-adhesive tape 42. Next, the bonding surface of the rear cover 41 is brought into contact with the thin film tube 43 and pressed. As a result, the rear cover 41 and the base unit 51 are bonded together with the thin film tube 43 being caught between the rear cover 41 and the double-adhesive tape 42. The double-adhesive tape 42 has such an elasticity as to allow the thin film tube 43 to sink thereinto.

On the other hand, the assembly for bonding the front cover 21 to the rear cover 41 is similar to that for the base unit 51 and the rear cover 41. More specifically, the front cover 21 corresponds to the rear cover 41, the double-adhesive tape 22 corresponds to the double-adhesive tape 42, and the thin film tube 23 corresponds to the thin film tube 43.

FIG. 9 is an explanatory view of a casing separation mechanism of the second embodiment. In the illustrated example, the rear cover 41 and the base unit 51 are bonded together with the double-adhesive tape 42. This structure differs from that of the first embodiment in that the thin film tube 43 is sandwiched between the double-adhesive tape 22 and the rear cover 41. The double-adhesive tape has a width of 3 mm and a thickness of 0.25 mm, in this embodiment. In this case, a width Ws of each bonding portion of the rear cover 41 and the base unit 51 is 3 mm. On the other hand, the thin film tube has a width Wt of about 1 mm and a thickness of about 0.1 mm, in this embodiment. Therefore, the rear cover 41 is pressed against the double-adhesive tape 42 and bonded thereto with the width of 2 mm with the thin film tube 43 sinking into the elastic double-adhesive tape 42. Further, the double-adhesive tape 42 is bonded to the base unit 51 with the width of 3 mm.

Upon detaching the rear cover 41 from the base unit 51, a fluid such as an air is filled into the thin film tube 43 through the air inlet 45 of the thin film tube 43 and the double-adhesive tape 42 is peeled off using the expansion force thereof to thereby detach the rear cover 41 from the base unit 51. The structure of the inlet 45 is similar to that of the first embodiment as shown in FIGS. 5A and 5B.

On the other hand, the casing separation mechanism for the front cover 21 and the base unit 51 is similar to the separation mechanism for the rear cover 41 and the base unit 51. More specifically, the front cover 21 corresponds to the rear cover 41, the double-adhesive tape 22 corresponds to the double-adhesive tape 42, and the thin film tube 23 corresponds to the thin film tube 43.

Further, the thin film tube may take various shapes such as a closed-loop shape or an open-loop shape such as an L-shaped form or a U-shaped form in accordance with the structure of the casing in addition to those described in the above embodiments. For example, as for the casing having the bonding surface on two sides, the thin film tube is formed into an L-shaped form and used to detach the cover from the two sides.

As described above, a fluid such as an air is filled into the thin film tube 23 and the thin film tube 43, which are set in advance upon assembly, to detach the component from the casing. Thus, any particular screwing structure is not necessary. Moreover, an external force is not directly applied to the front cover 21 or the rear cover 41. Thus, it is unnecessary to form a recess that looks unattractive, and the casing is not damaged and thus can be recycled. Further, a requisite operation is only to supply a fluid into the thin film tube 23 or the thin film tube 43 and thus can be performed with a syringe or a pump alone without requiring a special tool or skill.

What is claimed is:

1. A casing comprising:
an adhesive member;
a pair of casing members bonded together with the adhesive member; and
a tube including a fluid inlet and having an elasticity, the tube being provided between the pair of casing members, the tube expanding along with injection of a fluid into the tube from the fluid inlet to detach the bonded casing members based on an expansion force of the tube.

2. The casing according to claim 1, wherein the casing members include a tube holding groove formed in at least one of opposing surfaces and the tube is fit in the tube holding groove.

3. The casing according to claim 2, wherein the tube has an open-loop shape or a closed-loop shape.

4. The casing according to claim 1, wherein the tube is caught between the adhesive member and the casing members.

5. The casing according to claim 4, wherein the adhesive member is an elastic double-adhesive tape.

6. An electronic device comprising:
an electronic component;
a casing for incorporating the electronic component, the casing including
an adhesive member;
a pair of casing members bonded together with the adhesive member; and
a tube including a fluid inlet and having an elasticity, the tube being provided between the pair of casing members, the tube expanding along with injection of a fluid into the tube from the fluid inlet to detach the bonded casing members based on an expansion force of the tube.

7. The electronic device according to claim 6, wherein the casing members include a tube holding groove formed in at least one of opposing surfaces and the tube is fit in the tube holding groove.

8. The electronic device according to claim 7, wherein the tube has an open-loop shape or a closed-loop shape.

9. The electronic device according to claim 6, wherein the tube is caught between the adhesive member and the casing members.

10. The electronic device according to claim 9, wherein the adhesive member is an elastic double-adhesive tape.
